(19) United States
(12) Patent Application Publication
(10) Pub. No.: US 2004/0099789 A1
(43) Pub. Date: May 27, 2004

(54) Image sensor module having shortened optical path length and a film scanner using the same

(76) Inventor: Chin-Yuan Lin, Tai-Chung City (TW)

Correspondence Address: NAIPO (NORTH AMERICA INTERNATIONAL PATENT OFFICE), P.O. BOX 506, MERRIFIELD, VA, 22116, US

(21) Appl. No.: 10/065,901

(22) Filed: Nov. 27, 2002

(51) Int. Cl. H01L 27/00

(52) U.S. Cl. 250/208.1

(57) ABSTRACT

An image sensor module includes a body, an image sensor and a lens array. The image sensor is arranged within the body and includes a plurality of photosensitive units and a transparent layer for covering the photosensitive units. The transparent layer has an upper surface away from the photosensitive units. The lens array is arranged on the image sensor and in close contact with the upper surface of the transparent layer for receiving a plurality of image signals and focusing the image signals on the photosensitive units. The lens array has a depth of focus equal to a distance between the upper surface of the transparent layer and the photosensitive units.

### BACKGROUND OF INVENTION

1. Field of the Invention

The invention relates to an image sensor module, and in particular to an image sensor module having shortened optical path length and a film scanner using the same.

2. Description of the Related Art

Referring to FIG. 1, a conventional CIS (Contact Image Sensor) module 110 includes a body 111, an image sensor 112, a lens array 116, a cover glass layer 117, and a LED (Light Emitting Diode) 130.

The image sensor 112 is located at the bottom of the body 111 and includes a plurality of monochromatic, photosensitive units 113 and a transparent layer 114 for packaging the photosensitive units 113. The lens array 116 includes a plurality of rod lenses. It should be noted that the rod lenses and the photosensitive units 113 are arranged along a direction perpendicular to the drawing. The cover glass layer 117 covers the lens array 116 and the LED 130 to prevent dust from entering and influencing the image sensor module 110.

Light rays emitting from the LED 130 pass through the cover glass layer 117 via a light guide (not shown) and then illuminate on a reflective original 1. The reflective original 1 partially reflects the light rays, and the reflected light rays travel to the rod lenses of the lens array 116 and are focused onto the photosensitive units 113, respectively. Then, the image signals corresponding to the reflective original 1 may be obtained.

In the conventional CIS scanner, the length of the CIS module almost equals to the width of the to-be-scanned document. For example, the A4-sized CIS scanner utilizes the CIS module having a length of about 210 mm. Therefore, the object distance almost equals to the image distance with respect to the lens array 116, and the magnification equals to 1, which also means that the length of the CIS module almost equals to the width of the document. In addition, since the conventional CIS module utilizes the monochromatic sensor, the CIS module may perform color scanning using the LED 130 to emit light rays with different colors.

In the market available CIS sensors, a predetermined distance is left between the lens array 116 and the image sensor 112 so that the magnification equals to 1. However, since the brightness of the light rays may attenuate as the travel distance of the light rays increases, the exposure time during scanning has to be lengthened and the scanning process cannot be quickly performed. In addition, the image quality may deteriorate as the exposure time is lengthened.

Referring to FIG. 2, a CCD scanner mainly includes a CCD image sensor module 120 and a light source 124. The CCD image sensor module 120 includes a reflecting mirror 121, a lens 122 and a CCD image sensor 123.

The light source 124 emits light rays to pass through a film 2. Then, the reflecting mirror 121 reflects the light rays passing through the film 2. Subsequently, the reflected light rays pass through the lens 122 and are focused on the CCD image sensor 123. The light rays emitting from the light source 124 are usually white, while the CCD image sensor 123 includes red, green and blue photosensitive units. Thus, it is possible to perform color scanning.

In the conventional example, the optical path length from the film 2 to the CCD image sensor 123 is relatively long, and the brightness attenuation of light rays is also relatively great. Furthermore, the brightness of light rays may further be attenuated after the reflecting mirror 121 reflects the light rays. Moreover, it should be easily understood that the arrangement of the reflecting mirror in the scanner of FIG. 2 could not miniaturize the scanner.

### SUMMARY OF INVENTION

It is therefore an object of the invention to provide an image sensor module having shortened optical path length.

Another object of the invention is to provide a thin image sensor module so as to reduce the thickness of the film scanner utilizing the image sensor module.

Still another object of the invention is to provide an image sensor module capable of shortening the exposure time so as to speed up the scanning speed for the film scanner utilizing the image sensor module.

According to one aspect of the invention, an image sensor module includes a body, an image sensor and a lens array. The image sensor is arranged within the body and includes a plurality of photosensitive units and a transparent layer for covering the photosensitive units. The transparent layer has an upper surface away from the photosensitive units. The lens array is arranged on the image sensor and in close contact with the upper surface of the transparent layer for receiving a plurality of image signals and focusing the image signals on the photosensitive units. The lens array has a depth of focus equal to a distance between the upper surface of the transparent layer and the photosensitive units.

According to another aspect of the invention, a film scanner employing the above-mentioned image sensor module is provided.

According to the above-mentioned structure, the image sensor module of the invention may have the shortened optical path length to shorten the exposure time, speed up the scanning speed and stabilize the image quality.

### BRIEF DESCRIPTION OF DRAWINGS

FIG. 1 is a schematic illustration showing a conventional CIS (contact image sensor) module for scanning a reflective original.

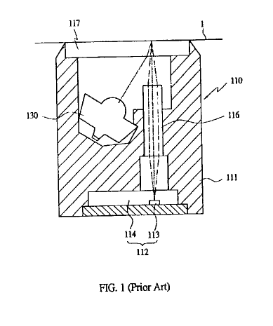

FIG. 2 is a schematic illustration showing a conventional CCD (charge coupled device) film scanner.

FIG. 3 is a schematic illustration showing a film scanner according to a first embodiment of the invention.

FIG. 4 is a schematic illustration showing a film scanner according to a second embodiment of the invention.

FIG. 5 is a schematic illustration showing a film scanner according to a third embodiment of the invention.

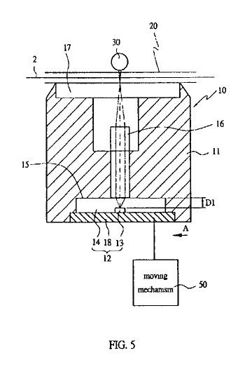

FIG. 6 is a schematic illustration showing a film scanner according to a fourth embodiment of the invention.

### DETAILED DESCRIPTION

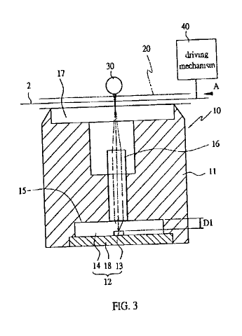

Referring to FIG. 3, a film scanner according to the first embodiment of the invention includes an image sensor module 10, a film passageway 20, a light source 30, and a driving mechanism 40.

The image sensor module 10 includes a body 11, an image sensor 12, a lens array 16 and a cover glass layer 17 arranged above the lens array 16 for covering the lens array 16. It should be noted that the cover glass layer 17 might be omitted so that the optical path length may further be shortened.

The image sensor 12 is arranged within the body 11 and includes a substrate 18, a plurality of photosensitive units 13 and a transparent layer 14 for covering the photosensitive units 13. The transparent layer 14 has an upper surface 15 away from the photosensitive units 13. The light source 30 passes through the film 2 to generate a plurality of image signals transferred to the lens array 16.

The lens array 16 may include a plurality of rod lenses and is positioned on the image sensor 12. Therefore, the lens array 16 is in close contact with the upper surface 15 of the transparent layer 14 to receive a plurality of image signals and focus the image signals on the photosensitive units 13. It should be noted that the rod lenses and the photosensitive units 13 are arranged in a direction perpendicular to the drawing. According to this structure, the depth of focus D1 of the lens array 16 equals to the distance between the upper surface 15 of the transparent layer 14 and the photosensitive units 13.

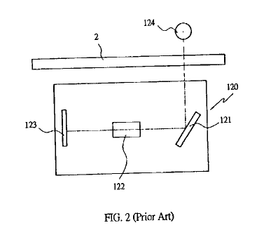

In this embodiment, the image sensor 12 may be similar to the CCD image sensor in FIG. 2 and include red, green, and blue photosensitive units so as to perform color scanning with respect to the film. In this case, the light source 30 may be the CCFL (Cold Cathode Fluorescent Lamp) or LED. It should be noted that the light source 30 might be a plane light source.

Because the depth of focus D1 is significantly reduced relative to the prior art, the optical path length is shortened and the attenuation amount of the light's brightness is greatly reduced. Therefore, the exposure time for scanning the film may be greatly shortened, and the scanning speed may thus be increased without deteriorating the image quality.

In this embodiment, the film 2 is driven by the driving mechanism 40 to move along the film passageway 20 in a direction indicated by the arrow A, while the image sensor module 10 is fixed to scan the film 2.

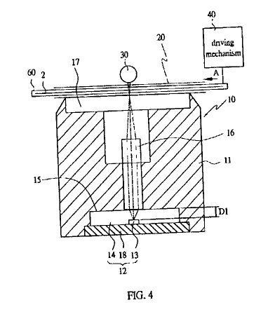

Please refer to FIG. 4, which is a schematic illustration showing a film scanner according to a second embodiment of the invention. This embodiment is almost identical to the first embodiment except for the difference where the film 2 is held and carried by a film holder 60 and the driving mechanism 40 is used to drive the film holder 60 to pass through the film passageway 20. According to this structure, a shorter film 2 may be conveniently held.

Please refer to FIG. S, which is a schematic illustration showing a film scanner according to a third embodiment of the invention. This embodiment is almost identical to the first embodiment except for the difference where the film 2 is fixed and a moving mechanism 50 is added. Thus, no driving mechanism is needed to drive the film 2 to move. During scanning, the image sensor module 10 is driven by the moving mechanism 50 to move along a direction as indicated by the arrow A. The moving image sensor module 10 may scan the film in the film passageway 20.

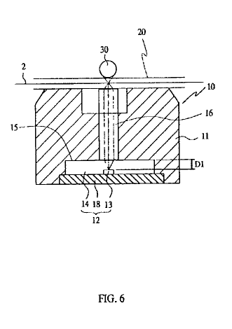

Please refer to FIG. 6, which is a schematic illustration showing a film scanner according to a fourth embodiment of the invention. This embodiment is almost identical to the first embodiment except for the difference where the cover glass layer 17 is omitted to greatly shorten the distance between the film 2 and the lens array 16. In this case, the thickness of the image sensor module 10 may be decreased to the minimum value, and the optical path length may be shortened to the minimum value, thereby meeting the object of shortening the exposure time of the invention.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. An image sensor module, comprising:
a body;
an image sensor arranged within the body and including a plurality of photosensitive units and a transparent layer for covering the photosensitive units, the transparent layer having an upper surface away from the photosensitive units; and
a lens array arranged on the image sensor and in close contact with the upper surface of the transparent layer for receiving a plurality of image signals and focusing the image signals on the photosensitive units, wherein a depth of focus of the lens array equals to a distance between the upper surface of the transparent layer and the photosensitive units.

2. The image sensor module according to claim 1, further comprising a cover glass layer located above the lens array for covering the lens array.

3. The image sensor module according to claim 1, wherein the photosensitive units include red, green, and blue photosensitive units.

4. A film scanner for scanning a film, the film scanner comprising:
an image sensor module comprising:
a body;
an image sensor arranged within the body and including a plurality of photosensitive units and a transparent layer for covering the photosensitive units, the transparent layer having an upper surface away from the photosensitive units; and
a lens array arranged on the image sensor and in close contact with the upper surface of the transparent layer for receiving a plurality of image signals and focusing the image signals on the photosensitive units, wherein a depth of focus of the lens array equals to a distance between the upper surface of the transparent layer and the photosensitive units;
a film passageway located above the image sensor module; and
a light source located above the film passageway for illuminating the film in the film passageway to generate the image signals.

5. The film scanner according to claim 4, wherein the image sensor module further comprises:
a cover glass layer located above the lens array for covering the lens array.

6. The film scanner according to claim 4, wherein the photosensitive units include red, green, and blue photosensitive units.

7. The film scanner according to claim 4, further comprising:
a driving mechanism for driving the film to pass through the film passageway.

8. The film scanner according to claim 4, further comprising:
a moving mechanism for moving the image sensor module to scan the film.

9. The film scanner according to claim 4, further comprising:
a film holder for holding the film; and
a driving mechanism for driving the film holder to pass through the film passageway.
